(19) United States
(12) Patent Application Publication
(10) Pub. No.: US 2011/0037070 A1
(43) Pub. Date: Feb. 17, 2011

(54) THIN FILM TRANSISTOR ARRAY PANEL AND METHOD FOR MANUFACTURING THE SAME

(76) Inventors: SUNG-RYUL KIM, Cheonan-shi (KR); Hyeong-Suk Yoo, Yongin-shi (KR); Byeong-Hoo Cho, Seoul (KR); O-Sung Seo, Seoul (KR); Seong-Hun Kim, Seoul (KR)

Correspondence Address: F. CHAU & ASSOCIATES, LLC, 130 WOODBURY ROAD, WOODBURY, NY, 11797, US

(21) Appl. No.: 12/820,461

(22) Filed: Jun. 22, 2010

(30) Foreign Application Priority Data
Aug. 14, 2009 (KR) 10-2009-0075435

(51) Int. Cl. H01L 29/786; H01L 21/336

(52) U.S. Cl. 257/57; 438/158; 257/E21.414; 257/E29.291

(57) ABSTRACT

A thin film transistor substrate includes a substrate including a display area and a peripheral area surrounding the display area, gate lines formed on the substrate including gate electrodes, an auxiliary insulating layer formed on the gate lines, a gate insulating layer formed on the auxiliary insulating layer and the gate lines, a semiconductor layer formed on the gate insulating layer, data lines formed on the semiconductor layer including source electrodes and drain electrodes, a passivation layer formed on the data lines, pixel electrodes formed on the passivation layer and electrically connected to the drain electrode, wherein the boundary line of the auxiliary insulating layer is located at or within the boundary of the gate line.

### CROSS-REFERENCE TO RELATED APPLICATION

The present application claims priority under 35 U.S.C. §119 to Korean Patent Application No. 10-2009-0075435, filed on Aug. 14, 2009, the disclosure of which is incorporated herein by reference in its entirety.

### BACKGROUND OF THE INVENTION

1. Technical Field

This invention is related to a thin film transistor substrate and method of manufacturing the same, and more particularly, to a thin film transistor substrate having an enhanced display quality.

2. Discussion of the Related Art

A liquid crystal display (LCD) device is one of the most widely used flat panel display devices. An LCD device includes two insulating substrates, each including field generating electrodes, and liquid crystal formed therebetween. The liquid crystal is aligned by an electric filed generated by the electrodes of the substrates, and the resulting alignment of the liquid crystal controls the amount of light that passes through the liquid crystal layer. A thin film transistor substrate may be used as a base substrate for a liquid crystal display device or electro luminescence display device. The thin film transistor substrate includes gate lines for carrying scanning signals, data lines for carrying display signals, thin film transistors electrically connected to the gate lines and the data lines, pixel electrodes electrically connected to the thin film transistors, a gate insulating layer, and a passivation layer covering the thin film transistors.

In a high resolution liquid crystal display device, signal delays and parasitic capacitances are caused by the narrow width and long length of the gate or data lines. To prevent or minimize the signal delays and parasitic capacitances, thick, low resistance metal lines or thick insulating layers have been used.

However, thick metal lines may lead to an open circuit and forming thick insulating layers may lead to a productivity decrease and deterioration of electric capability of the thin film transistor channel area.

### SUMMARY OF THE INVENTION

Exemplary embodiments of the present invention provide a thin film transistor substrate having an enhanced display quality and a method of manufacturing the same.

According to an exemplary embodiment of the present invention, a thin film transistor substrate includes a substrate including a display area and a peripheral area surrounding the display area, gate lines formed on the substrate including gate electrodes, an auxiliary insulating layer formed on the gate lines, a gate insulating layer formed on the auxiliary insulating layer and the gate lines, a semiconductor layer formed on the gate insulating layer, data lines formed on the semiconductor layer including source electrodes and drain electrodes, a passivation layer formed on the data lines, pixel electrodes formed on the passivation layer and electrically connected to the drain electrode, wherein the boundary line of the auxiliary insulating layer is located at or within the boundary of the gate line.

The auxiliary insulating layer may include an open portion exposing a portion of the gate electrode between the source electrode and the drain electrode.

The auxiliary insulating layer and the gate line may have substantially the same pattern except for the open portion exposing a portion of the gate electrode between the source electrode and the drain electrode.

The gate insulating layer may contact the portion of the gate electrode between the source electrode and the drain electrode.

A dielectric constant of the auxiliary insulating layer may be from about 2.5 to about 3.5.

The auxiliary insulating layer may include one of SiOC:H, SiO2, FSG (Fluorosilicate Glass), DLC (Diamond-Like Carbon), SiOC (Black Diamond), Parylene-N, Fluorinated DLC, Parylene-F, Polyimides, HSQ (Hydrogen Silsesquioxane), B-stage Polymer, Fluorinated Polyimides, MSQ (Methyl Silsesquioxane), PAE (Poly Arylene Ether), PTFF, Porous silica (Aerdogels/Xerogels), Porous HSQ, porous SiLK, porous MSQ, Porous PAE.

A thickness of the auxiliary insulating layer ranges from about 1,000Å to about 1 μm.

The semiconductor layer formed on the gate insulating layer includes a channel portion between the source electrode and the drain electrode.

The semiconductor layer may include amorphous silicon. An n+ doped amorphous silicon layer may be deposited on the semiconductor layer. The pattern of n+ doped amorphous silicon layer may be substantially the same as that of the data lines.

The passivation layer may include an open portion exposing the drain electrode, and the pixel electrode may be electrically connected to the drain electrode through the open portion of the passivation layer.

According to an exemplary embodiment of the present invention, a method of manufacturing a thin film transistor substrate includes forming gate lines including gate electrodes on an insulating substrate, forming an auxiliary insulating layer within the area of gate lines, forming a gate insulating layer covering the auxiliary insulating layer, forming a semiconductor layer on the gate insulating layer, forming an ohmic contact layer on the semiconductor layer, forming data lines including source electrodes and drain electrodes on the ohmic contact layer, forming a passivation layer on the data lines, and forming pixel electrodes electrically connected to the drain electrode on the passivation layer.

Forming the gate lines and the auxiliary insulating layer includes forming a gate metal layer and a first insulating layer on the insulating substrate, forming a first photo resist pattern including a first portion and a second portion thicker than the first portion on the first insulating layer, forming a gate line pattern and an insulating layer pattern by etching the gate metal layer and the first insulating layer using the first photo resist pattern as a mask, forming a second photoresist pattern by removing the first portion of the first photo resist pattern by an etch back process, forming the auxiliary insulating layer by etching the insulating pattern by using the second photo resist pattern as a mask.

The first portion of the first photo resist pattern may be located on a portion of the first insulating layer corresponding to the gate electrode.

Forming the semiconductor layer, ohmic contact layer, and data lines including source and drain electrodes includes forming an amorphous silicon layer on the gate insulating layer, forming an n+ doped amorphous silicon layer, and forming a data metal layer on the n+ doped amorphous silicon layer, forming a third photoresist portion including a third portion and a fourth portion thicker than the third portion on the data metal layer, forming a data metal pattern, an n+ doped amorphous silicon layer pattern, and the semiconductor layer by etching the data metal layer, n+ doped amorphous silicon layer, and the amorphous silicon layer by using the third photoresist pattern as a mask, forming a fourth photoresist pattern by removing the third portion of the third photoresist pattern by an etch back process, forming the ohmic contact layer, and data lines including source and drain electrode by etching the doped amorphous silicon layer pattern and data metal pattern using the fourth photo resist pattern as a mask.

The third portion of the third photoresist pattern may be located in an area corresponding to the gate electrode and a channel area between the source and drain electrode.

Forming the passivation layer and pixel electrode includes forming a second insulating layer on the data line and the drain electrode, forming a fifth photoresist pattern on the second insulating layer, forming the passivation layer by etching the second insulating layer by using the fifth photoresist pattern as a mask, forming a pixel electrode by patterning a conductive electrode layer formed on the passivation layer.

The dielectric constant of the auxiliary insulating layer ranges from about 2.5 to about 3.5.

### BRIEF DESCRIPTION OF THE DRAWINGS

Exemplary embodiments of the present invention can be understood in more detail from the following descriptions taken in conjunction with the accompanying drawings, in which:

FIG. 1 is a cross sectional view of a thin film transistor substrate including a thin film transistor according to an exemplary embodiment of the present invention.

FIG. 2 is a plan view of a pixel according to an exemplary embodiment of the present invention.

FIG. 3 is a cross sectional view taken along lines III-III′, III″-III′″, and III″″-III′″″ of FIG. 2.

FIG. 4 to FIG. 8 are cross sectional view showing a method of manufacturing a thin film transistor substrate taken along a line III″-III″′ of FIG. 2.

FIG. 9 is a cross sectional view of a thin film transistor substrate including a thin film transistor according to an exemplary embodiment of the present invention.

### DETAILED DESCRIPTION OF EXEMPLARY EMBODIMENTS

The invention is described more fully hereinafter with reference to the accompanying drawings, in which exemplary embodiments of the invention are shown. This invention may, however, be embodied in many different forms and should not be construed as limited to the exemplary embodiments set forth herein.

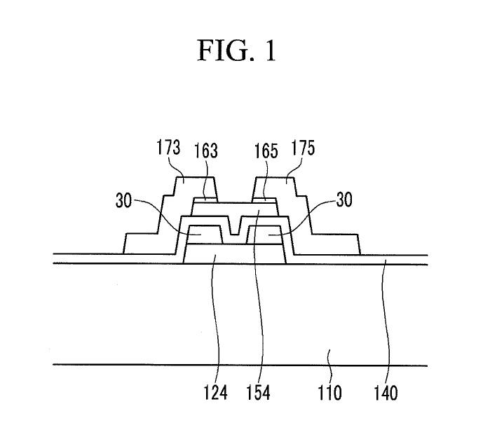

FIG. 1 is a cross sectional view of a thin film transistor substrate including a thin film transistor according to an exemplary embodiment of the present invention. Referring to FIG. 1, gate electrode (124) is formed on the insulating substrate (110) and auxiliary insulating layer (30) is formed on the gate electrode (124).

The auxiliary insulating layer (30) includes portions facing each other on the gate electrode (124), and has a dielectric constant that ranges from about 2.5 to about 3.5. The material for the auxiliary insulating layer (30) may include, for example, one of SiOC:H, SiO2,FSG (Fluorosilicate Glass), DLC (Diamond-Like Carbon), SiOC (Black Diamond), Parylene-N, Fluorinated DLC, Parylene-F, Polyimides, HSQ (Hydrogen Silsesquioxane), B-stage Polymer, Fluorinated Polyimides, MSQ (Methyl Silsesquioxane), PAE(Poly Arylene Ether), PTFF, porous silica (Aerdogels/Xerogels), porous HSQ, porous SiLK, porous MSQ, and porous PAE. The thickness of the auxiliary insulating layer (30) may range from about 1,000Å to about 1 μm.

The gate insulating layer (140) is fowled on the auxiliary insulating layer (30), and includes a portion that contacts the gate electrode (124). The gate insulating layer (140) may include, for example, one SiNx, SiOx, HfOx, AlOx, ZrOx, AlN, AlNO, TiOx, BaTiO₃, PbTiO₃, Pb[ZrTi]O₃, and [PbLa][ZrTi]O₃. Semiconductor layer (154) including, for example, hydrogenated amorphous silicon or polysilicon, is formed on the gate insulating layer (140).

On the semiconductor layer (154), ohmic contact layer (163, 165) may be formed. The ohmic contact layer (163, 165) may include, for example, silicide or an n+ hydrogenated amorphous silicon layer where impurities like phosphorus are doped.

The source electrode (173) and the drain electrode (175) are formed on the ohmic contact layer (163, 165) and gate insulating layer (140).

A channel is formed between the source electrode (173) and the drain electrode (175). According to the embodiment of the present invention, the gate insulating layer (140) contacts the gate electrode (124) where the channel is formed. The auxiliary insulating layer (30), which has a low dielectric constant, is formed on the remaining portion of the gate electrode (124). Thus, parasitic capacitance (Cgs) between the source electrode and the gate electrode can be reduced due to an increase of thickness between the gate electrode and source electrode.

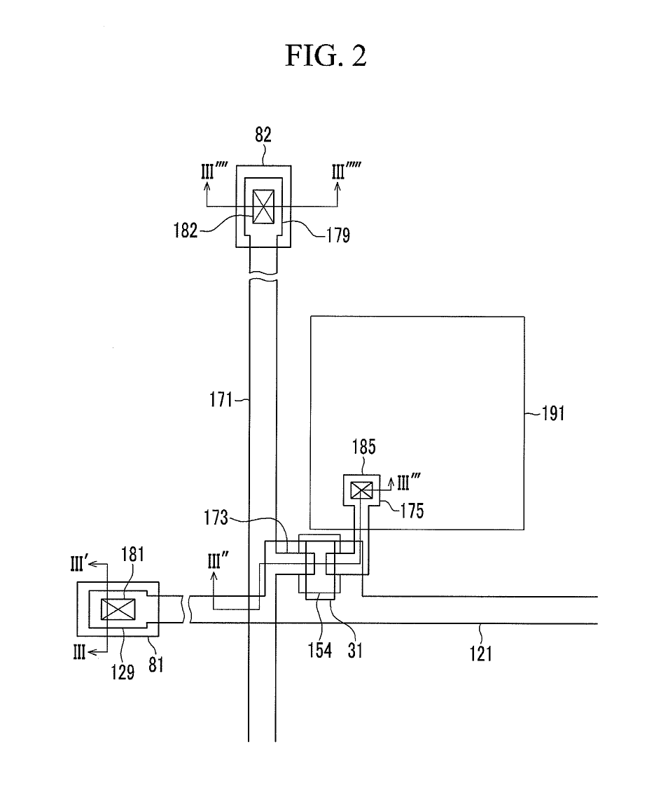

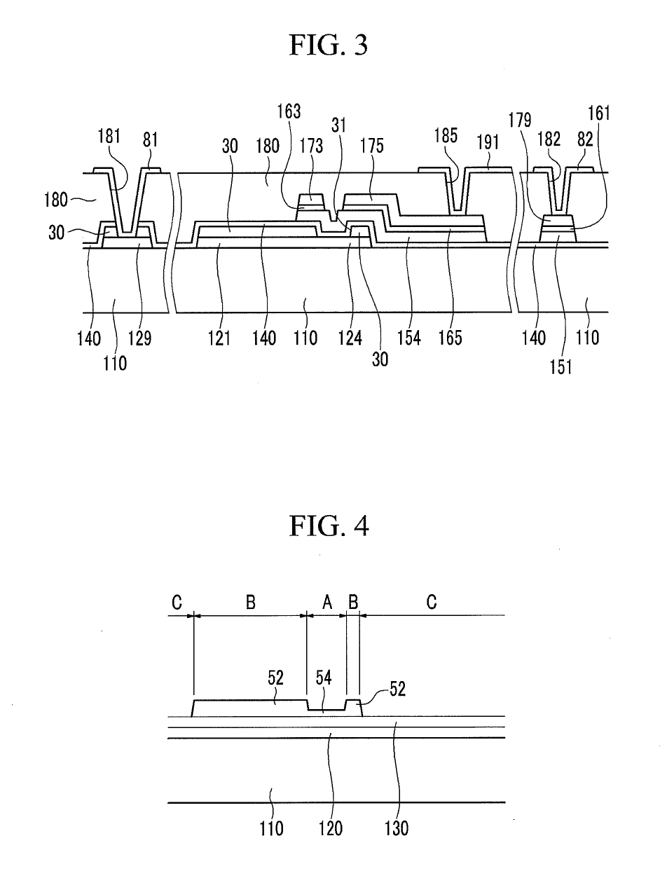

FIG. 2 is a plan view of a pixel according to an exemplary embodiment of the present invention. FIG. 3 is a cross sectional view taken along lines III-III′, and III″-III′″, and III″″-III″″′ of FIG. 2.

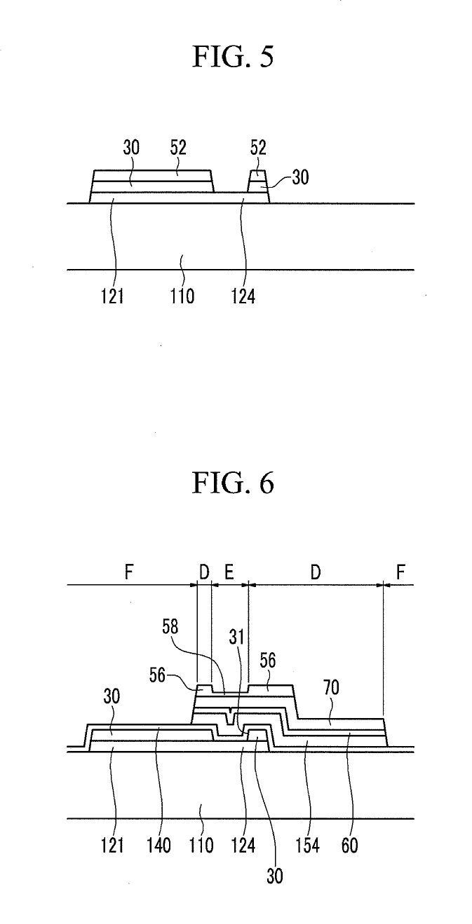

Referring to FIG. 2 and FIG. 5, plurality of gate lines (121) is formed on the insulating substrate (110). The insulating substrate may be formed of, for example, transparent glass or plastic. The gate line (121) transmits a scanning signal. The gate line (121) includes a gate electrode (124) which is protruded from the gate line (121) and gate pad (129) for electrical connection with, for example, an outside driving circuit. The auxiliary insulating layer (30) is formed on the gate line (121). Portions of the auxiliary insulating layer corresponding to the gate electrode (124) face each other, and have a dielectric constant ranging from about 2.5 to about 3.5. The auxiliary insulating layer (30) may include, for example, at least one of SiOC:H, SiO2, FSG (Fluorosilicate Glass), DLC (Diamond-Like Carbon), SiOC (Black Diamond), Parylene-N, Fluorinated DLC, Parylene-F, Polyimides, HSQ (Hydrogen Silsesquioxane), B-stage Polymer, Fluorinated Polyimides, MSQ (Methyl Silsesquioxane), PAE (Poly Arylene Ether), PTFF, porous silica (Aerdogels/Xerogels), porous HSQ, porous SiLK, porous MSQ, porous PAE. The thickness of the auxiliary insulating substrate (30) ranges from about 1,000Å to about 1 μm.

The auxiliary insulating layer (30) includes an open portion (31) to expose a portion of the gate electrode (124). The auxiliary insulating layer (30) may have substantially the same pattern as the gate line (121) except for the open portion (31).

The gate insulating layer (140) is formed on the auxiliary insulating layer (30). The gate insulating layer may include same material as described above in the explanation of FIG. 1. According to an embodiment of the invention, silicon nitride is used for forming gate insulating layer (140). The semiconductor layer (151) is formed on the gate insulating layer (140), and made of, for example, hydrogenated amorphous silicon or polysilicon. The semiconductor layer (151) includes protruded portion (154) at the area corresponding to the gate electrode (124).

Ohmic contact portions (161, 165) are formed on the semiconductor layer (151). The ohmic contact portion (161) includes a plurality of protruded portions (163).

A plurality of data lines (171) and a plurality of drain electrodes (175) are formed on the ohmic contact layer (161, 165) and the gate insulating layer (140).

The data lines (171) intersect with the gate lines (121), and transmit data signals. The data lines include source electrodes (173) and pad portions (179) for electrically connecting with, for example, external driving circuits.

The drain electrode (175) faces source electrode (173). The source electrode (173) is formed on protruded portion (163).

The thin film transistor includes one gate electrode (124), one source electrode (173), one drain electrode (175), and protruded portion (154) of the semiconductor layer (151). The channel is formed on the protruded portion (154) between the source electrode (173) and drain electrode (175).

The ohmic contact layer (161, 165) is formed between the semiconductor layer (151) and source electrode (173) connected to the data line (171) and drain electrode (175). The ohmic contact layer (161, 165) reduces contact resistance between the source—drain electrode and the semiconductor layer (151). The ohmic contact layer (161, 165) and the semiconductor layer (151), except the protruded portion (154), have substantially the same pattern with data lines (171) and drain electrodes (175).

A passivation layer (180) is formed on the data lines (171), drain electrodes (175) and the exposed protruded portion (154) of the semiconductor layer (151). The passivation layer (180) is made of, for example, one of SiNx, SiOx, organic insulating material, or low dielectric insulating material.

A contact hole (185) is formed in the passivation layer (180) and exposes a portion of the drain electrode (175).

Pixel electrodes (191) and contact assistants (81, 82) are formed on the passivation layer (180). The pixel electrode (191) is electrically connected to the drain electrode (175) through the contact hole (185), and receives a data signal voltage. The pixel electrode (191) forms an electric field with a common electrode receiving a common voltage. The direction of the liquid crystal is controlled by the electric field.

The pixel electrode (191) may form a storage capacitor with a storage electrode line (not shown), and the storage capacitor enhances the liquid crystal capacitor's voltage maintaining ability.

The contact assistants (81, 82) are connected with an end portion (129) of the gate line (121) and an end portion (179) of the data line (171), respectively. The contact assistants (81, 82) enhance the adhesion between the end portions (129, 179) and external devices to which the end portions are connected, such as, the external driving circuit.

The pixel electrodes (191) and contact assistants (81, 82) may be made of transparent conducting material such as ITO, IZO.

According to an exemplary embodiment of the invention, the auxiliary insulating layer (30) can reduce the parasitic capacitance at the portion where the gate line and data line overlap with each other. The decrease of the parasitic capacitance results in decreasing the signal delays of the gate line. By forming the open portion (31) of the auxiliary insulating layer (30) on the portion corresponding to the gate electrode (124), the switching ability of the thin film transistor is enhanced without changing a gate on-off voltage. As a result, the size of the thin film transistor can be reduced and the aperture ratio can be increased because the electrical characteristics can be enhanced without increasing the size of the channel.

The gate lines and the auxiliary insulating layer may be formed simultaneously, so that an additional photo lithography process is not required.

A method of manufacturing the thin film transistor substrate according to an embodiment of the invention will be explained.

FIG. 4 to FIG. 8 are cross sectional views showing a method of manufacturing a thin film transistor substrate taken along the lines III-III′ and III″-III″′ of FIG. 2.

Referring to FIG. 4, a metal layer (120) and insulating layer (130) including low dielectric material is formed on an insulating substrate (110) such as glass or plastic.

A photoresist layer is deposited. The photoresist layer pattern (52, 54), including portions having different thicknesses, is formed on the insulating layer (130) by an exposure and develop process. A portion of the insulating layer (130) and metal layer (120) corresponding to the channel area is referred as a first channel portion (A), a portion corresponding to the gate line is referred as a first line portion (B), and the remaining portions, except portion A and portion B, are referred to as a residue portion (C).

A portion of the photoresist layer (52) corresponding to the first line portion (B) is thicker than the portion A, and the portion corresponding to residue portion (C) is removed. In this process, the thickness ratio between A and B portion may differ according to the process conditions. According to an embodiment, the thickness of the portion B is less than half of the thickness of the portion B.

A method of forming portions of the photoresist layer with different thicknesses may be, for example, a slit mask method or half tone mask method. Reflow method is another method performed by reflowing the photo resist pattern.

Referring to FIG. 5, gate line (121) including gate electrode (124) is formed by etching the insulating layer (130) and the metal layer (120) using the photoresist pattern (52, 54) as a mask.

By an etch back process for the photo resist pattern (52, 54), the first portion (A) of the photoresist pattern is removed and the portion (B) of the photoresist pattern remains with a thinner thickness than before the etch back process. The auxiliary insulating layer (30) is formed by etching the insulating layer (130) using the photo resist pattern (52) as a mask. An undercut(s) beneath the auxiliary insulating layer (30) may be formed due to the difference of the etch rates between the auxiliary insulating layer (30) and the gate line (121) during the removing process of the photo resist pattern (54) corresponding to the first channel pattern (A). The undercut(s) is removed by performing another etching of the auxiliary insulating layer (30).

With the exception of the open portion (31), which exposes a certain area of the gate electrode (124), the auxiliary insulating layer (30) has substantially the same pattern as the gate line (121).

Referring to FIG. 6, the gate insulating layer (140) is formed to cover the gate lines (121) after removing the photo resist pattern (52). The gate insulating layer (140) contacts the gate electrode (124) at a portion corresponding to the channel area.

An amorphous silicon layer and doped amorphous silicon layer are formed by a chemical vapor deposition method. The metal layer for the data lines is deposited by using sputtering.

The photoresist pattern (56, 58), including portions having different thicknesses from each other, is formed by an exposure and develop process after depositing a photoresist layer on the metal layer for the data lines. The portion of the data metal layer corresponding to the data lines, doped amorphous silicon layer, and amorphous silicon layer is referred as a second line portion (D). The portion of the data metal layer corresponding to the channel portion on the gate electrode (124) is referred as a second channel portion (E). The remaining portion, except portion D and portion E, is referred as a second residue portion (F).

The portion of the photoresist layer (56) corresponding to the second line portion (D) is thicker than that of the second channel portion (E), and the portion corresponding to the second residue portion (F) is removed.

In the following process, a data line pattern (70), ohmic contact layer (60), and semiconductor layer (151) including protrusion (154) are formed by etching using the photoresist pattern (56, 58) as a mask.

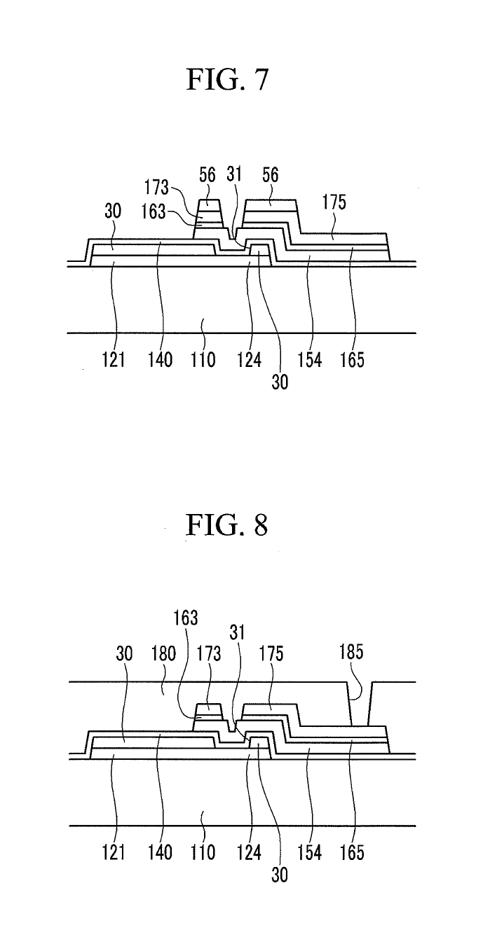

Referring to FIG. 7, the second channel portion (58) of the photoresist pattern (56, 58) is removed by an etch back process. During this process, the thickness of the photoresist pattern (56) corresponding to the second line portion (D) is decreased. The data lines (171) including source electrode (173), and drain electrode (175), and ohmic contact layer portion (163, 165) are formed by etching the metal layer for the data lines, and the ohmic contact layer using the remaining photo resist pattern (56) as a mask.

The data lines (171) and drain electrodes (175) have substantially the same pattern as the ohmic contact layer portion (163, 165), and as the semiconductor layer (151) except for the channel portion.

Referring to FIG. 8, the passivation layer (180) is formed to cover the protrusion portion of the semiconductor layer (154), and includes contact hole (185), formed by a photolithography process, to expose a certain area of the drain electrode (175).

In a following process, the pixel electrode (191) is formed and electrically connected to the drain electrode (175) through the contact hole (185).

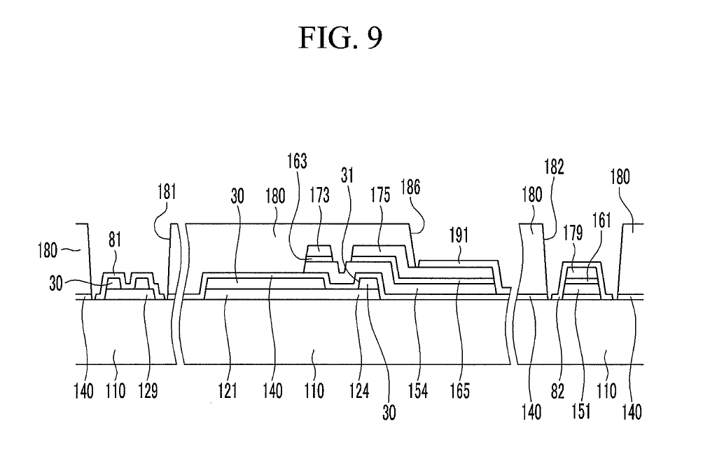

FIG. 9 is a cross sectional view of a thin film transistor substrate including a thin film transistor according to an exemplary embodiment of the present invention. The thin film transistor substrate has different passivation layer (180) and pixel electrode (191) shape than the thin film transistor substrate according to the FIGS. 2 and 3.

In the thin film transistor substrate according to FIG. 9, the passivation layer (180) has pixel open portion (186) exposing portions of the drain electrode (175) and the gate insulating layer (140). The pixel electrode (191) is located within the pixel open portion (186), and contacts to drain electrode (175) and gate insulating layer (140). A planar shape of the pixel electrode (191) is substantially the same as the shape of the pixel open portion (186). The passivation layer (180) includes contact holes (181, 182) exposing the end portion of the gate line (129) and the end portion of the data line (179), respectively. Contact assistant portions (81, 82) are formed inside the contact holes (181, 182), respectively.

This structure may be formed by a lift off method. The lift off method includes forming an insulating layer for the passivation layer (180), and forming a photoresist pattern on the insulating layer for the passivation layer (180). The photo resist pattern may be formed in a matrix shape along the data lines (171) and the gate lines (121), and exposes the end portion (129) of the gate line and the end portion (179) of the data line.

In a following process, the passivation layer (180) is formed including opening portion (186) and the contact holes (181, 182) by etching the insulating layer for the passivation layer (180) using the photoresist pattern as a mask.

In a following process, an electrode layer for the pixel electrode is formed and the photoresist pattern is removed, and then the opening portion of the passivation layer (180) and the contact holes (181, 182) are formed as a result.

Although the illustrative embodiments of the present invention have been described herein with reference to the accompanying drawings, it is to be understood that the present invention should not be limited to those precise embodiments and that various other changes and modifications may be affected therein by one of ordinary skill in the related art without departing from the scope or spirit of the invention. All such changes and modifications are intended to be included within the scope of the invention as defined by the appended claims.

What is claimed is:

1. A thin film transistor substrate comprising;
an insulating substrate;
a gate line including a gate electrode formed on the insulating substrate;
an auxiliary insulating layer on the gate line;
a gate insulating layer on the auxiliary insulating layer and the insulating substrate;
a semiconductor layer formed on the gate insulating layer;
a data line including a source electrode overlapping the semiconductor layer;
a drain electrode facing the source electrode and overlapping the semiconductor layer;
a passivation layer formed on the data line and the drain electrode;
a pixel electrode formed on the passivation layer and electrically connected to the drain electrode,
wherein a boundary of the auxiliary insulating layer is located at or within a boundary of the gate line.

2. The thin film transistor substrate of claim 1, wherein the auxiliary insulating layer comprises an open portion exposing the gate electrode between the source electrode and the drain electrode.

3. The thin film transistor substrate of claim 2, wherein the auxiliary insulating layer comprises substantially same pattern as the gate line except for the open portion.

4. The thin film transistor substrate of claim 3, wherein the gate insulating layer contacts the gate electrode through the open portion.

5. The thin film transistor substrate of claim 1, wherein the dielectric constant of the auxiliary insulating layer ranges from about 2.5 to about 3.5.

6. The thin film transistor substrate of claim 5, wherein the auxiliary insulating layer comprises at least one of SiOC:H, SiO2,fluorosilicate glass, diamond-like carbon, SiOC, Parylene-N, fluorinated diamond-like carbon, parylene-F, polyimides, hydrogen silsesquioxane, B-stage polymer, fluorinated polyimides, methyl silsesquioxane, poly arylene ether, PTFF, porous silica, porous hydrogen silsesquioxane, porous SiLK, porous methyl silsesquioxane, and porous poly arylene ether.

7. The thin film transistor substrate of claim 5, wherein a thickness of the auxiliary insulating layer ranges from about 1,000Å to about 1 μm.

8. The thin film transistor substrate of claim 1, wherein the semiconductor layer is located beneath the data line and the drain electrode, and comprises a channel portion between the source electrode and the drain electrode.

9. The thin film transistor substrate of claim 8, wherein the semiconductor layer further comprises an n+ doped amorphous silicon layer, and wherein the n+ doped amorphous silicon layer has substantially the same pattern as the data line and drain electrode.

10. The thin film transistor substrate of claim 9, wherein the passivation layer comprises a pixel open portion exposing a portion of the drain electrode and the gate insulating layer, and wherein the pixel electrode is located within the pixel open portion and is electrically connected with the drain electrode.

11. The thin film transistor substrate of claim 10, wherein a planar shape of the pixel electrode is substantially the same as a planar shape of the pixel open portion.

12. The thin film transistor substrate of claim 1, wherein the passivation layer comprises a pixel open portion exposing the drain electrode and the gate insulating layer, and wherein the pixel electrode is located within the pixel open portion and is electrically connected with the drain electrode.

13. The thin film transistor substrate of claim 12, wherein a planar shape of the pixel electrode is substantially the same as a planar shape of the pixel open portion.

14. A method of manufacturing a thin film transistor substrate, the method comprising:
forming a gate line including a gate electrode on a insulating substrate;
forming an auxiliary insulating layer within an area of the gate line;
forming a gate insulating layer covering the auxiliary insulating layer;
forming a semiconductor layer on the gate insulating layer;
forming an ohmic contact assistant layer on the semiconductor layer;
forming a data line including a source electrode and a drain electrode on the ohmic contact assistant layer;
forming a passivation layer on the data line and drain electrode; and
forming a pixel electrode on the passivation layer, wherein the pixel electrode is electrically connected to the drain electrode.

15. The method of claim 14, wherein forming the gate line and the auxiliary insulating layer comprises:
forming a gate metal layer and a first insulating layer on the insulating substrate;
forming a first photoresist pattern including a first portion and a second portion on the first insulating layer, wherein the second portion is thicker than the first portion;
forming an insulating layer pattern and the gate line including the gate electrode by etching the first insulating layer and the gate metal layer using the first photoresist pattern as a mask;
forming a second photoresist pattern by performing an etch back process on the first photoresist pattern; and
forming the auxiliary insulating layer by etching the insulating layer pattern using the second photoresist pattern as a mask;

16. The method of claim 15, wherein the first portion is located on a portion of the first insulating layer corresponding to the gate electrode.

17. The method of claim 16, wherein forming the semiconductor layer and ohmic contact assistant layer, data line, and drain electrode comprises:
forming an amorphous silicon layer, an impurity doped amorphous silicon layer, and a data metal layer on the gate insulating layer;
forming a third photoresist pattern including a third portion and a fourth portion thicker than the third portion on the data metal layer;
forming a data metal layer pattern, a doped amorphous silicon layer pattern, and the semiconductor layer by etching the data metal layer, the impurity doped amorphous silicon layer, and the amorphous silicon layer using the third photoresist pattern as a mask;
forming a fourth photoresist pattern by performing an etch back process on the third photoresist pattern; and
forming the ohmic contact assistant layer, data line, and drain electrode by etching the doped amorphous silicon layer pattern and data metal layer pattern using the fourth photoresist pattern as a mask.

18. The method of claim 17, wherein the third portion is located on a portion corresponding to a channel area between the source electrode and the drain electrode.

19. The method of claim 18, wherein forming the passivation layer and forming the pixel electrode comprises:
forming a second insulating layer on the data line and the drain electrode;
forming a fifth photoresist pattern on the second insulating layer;
forming the passivation layer by etching the second insulating layer using the fifth photoresist pattern as a mask;
forming a transparent electrode on the fifth photoresist pattern; and
forming the pixel electrode by removing the fifth photoresist pattern.

20. The method of claim 14, wherein forming the semiconductor layer, forming the ohmic contact layer, the data line, and the drain electrode comprises;
forming an amorphous silicon layer, an impurity doped amorphous silicon layer, and a data metal layer on the gate insulating layer;
forming a first photoresist pattern including a first portion and a second portion thicker than the first portion on the data metal layer;
forming a data metal layer pattern, a doped amorphous silicon layer pattern, and the semiconductor layer by etching the data metal layer, impurity doped amorphous silicon layer, and the amorphous silicon layer using the first photoresist pattern as a mask;
forming a second photoresist pattern by performing an etchback process on the first photoresist pattern;
forming the ohmic contact assistant layer, data line, and drain electrode by etching the doped amorphous silicon layer pattern and data metal layer pattern using the second photoresist pattern as a mask.

21. The method of claim 20, wherein the first portion is located on a portion corresponding to a channel area between the source electrode and the drain electrode.

22. The method of claim 14, wherein forming the passivation layer and forming of the pixel electrode comprises;
forming an insulating layer on the data line and the drain electrode;
forming a photoresist pattern on the insulating layer;
forming the passivation layer by etching the insulating layer using the photoresist pattern as a mask;
forming a transparent electrode on the photo resist pattern; and
forming the pixel electrode by removing the photoresist pattern.

23. The method of claim 14, wherein the dielectric constant of the auxiliary insulating layer ranges from about 2.5 to about 3.5.
